(19) United States
(12) Patent Application Publication
(10) Pub. No.: US 2015/0255267 A1
(43) Pub. Date: Sep. 10, 2015

(54) Atomic Layer Deposition of Aluminum-doped High-k Films

(71) Applicant: Tokyo Electron Limited, Tokyo (JP)

(72) Inventors: Kandabara N. Tapily, Mechanicville, NY (US); Robert D. Clark, Livermore, CA (US); Steven P. Consiglio, Albany, NY (US); Cory Wajda, Sand Lake, NY (US); Gerrit J. Leusink, Rexford, NY (US)

(21) Appl. No.: 14/642,173

(22) Filed: Mar. 9, 2015

Related U.S. Application Data
(60) Provisional application No. 61/950,200, filed on Mar. 9, 2014.

(51) Int. Cl. H01L 21/02

(52) U.S. Cl. CPC H01L 21/0228; H01L 21/02181; H01L 21/02178; H01L 21/022

(57) ABSTRACT

Embodiments of the invention describe methods for forming a semiconductor device. According to one embodiment, the method includes depositing an aluminum-doped high-k film on a substrate by atomic layer deposition (ALD) that includes: a) pulsing a metal-containing precursor gas into a process chamber containing the substrate, b) pulsing an aluminum-containing precursor gas into the process chamber, where a) and b) are sequentially performed without an intervening oxidation step, and c) pulsing an oxygen-containing gas into the process chamber. The method can further include heat-treating the aluminum-doped high-k film to crystallize or increase the crystallization of the film.

### CROSS-REFERENCE TO RELATED APPLICATIONS

This application is related to and claims priority to U.S. Provisional application Ser. No. 61/950,200 filed on Mar. 9, 2014, the entire contents of which are herein incorporated by reference.

### FIELD OF THE INVENTION

The present invention generally relates to a method of forming a high dielectric constant (high-k) film for a semiconductor device, and more particularly to a method of forming an aluminum-doped high-k film.

### BACKGROUND OF THE INVENTION

The semiconductor industry is characterized by a trend toward fabricating larger and more complex circuits on a given semiconductor chip. The larger and more complex circuits are achieved by reducing the size of individual devices within the circuits and spacing the devices closer together.

High-k films, and in particular HfO₂-based dielectrics, have successfully replaced SiO₂ in the state of art CMOS technology. In order to integrate HfO₂-based gate dielectrics into more complex circuits, the equivalent oxide thickness (EOT) may be reduced by scaling the overall dielectric thickness or increasing the dielectric constant. The thermodynamically stable phase of HfO₂, monoclinic, has a dielectric constant of about 16 which is comparable to the dielectric constant of amorphous HfO₂. The tetragonal and cubic phases of HfO₂ which are stabilized at elevated temperatures have dielectric constants of about 70 and about 30, respectively. New methods for forming HfO₂-based films with higher dielectric constants than that of monoclinic HfO₂ can thus enable further scaling of the HfO₂-based gate dielectric.

### SUMMARY OF THE INVENTION

According to one embodiment, a method is provided for forming a semiconductor device. The method includes depositing an aluminum-doped high-k film on a substrate by atomic layer deposition (ALD) that includes: a) pulsing a metal-containing precursor gas into a process chamber containing the substrate, b) pulsing an aluminum-containing precursor gas into the process chamber, where a) and b) are sequentially performed without an intervening oxidation step, and c) pulsing an oxygen-containing gas into the process chamber. The method can further include heat-treating the aluminum-doped high-k film to crystallize or increase the crystallization of the film.

According to another embodiment, the method includes depositing a metal oxide film on a substrate, and depositing an aluminum-doped high-k film on the metal oxide film, where the aluminum-doped high-k film is deposited by ALD that includes: a) pulsing a metal-containing precursor gas into a process chamber containing the substrate, b) pulsing an aluminum-containing precursor gas into the process chamber, where a) and b) are sequentially performed without an intervening oxidation step, and c) pulsing an oxygen-containing gas into the process chamber.

According to yet another embodiment, the method includes depositing a first metal oxide film on a substrate, depositing an aluminum-doped high-k film on the metal oxide film, where the aluminum-doped high-k film is deposited by ALD that includes: a) pulsing a metal-containing precursor gas into a process chamber containing a substrate, b) pulsing an aluminum-containing precursor gas into the process chamber, where a) and b) are sequentially performed without an intervening oxidation step, and c) pulsing an oxygen-containing gas into the process chamber, and depositing a second metal oxide film on the aluminum-doped high-k film.

### BRIEF DESCRIPTION OF THE DRAWINGS

In the accompanying drawings:

FIG. 1 shows a process flow diagram for forming a semiconductor device according to an embodiment of the invention;

FIG. 2 shows a process flow diagram for forming a semiconductor device according to another embodiment of the invention;

FIG. 3 shows a process flow diagram for forming a semiconductor device according to another embodiment of the invention;

FIGS. 4A-4D show through cross-sectional views a method for forming a semiconductor device according to an embodiment of the invention;

FIGS. 5A-5B show through cross-sectional views a method for forming a semiconductor device according to another embodiment of the invention;

FIG. 6 shows equivalent oxide thickness (EOT) as a function of aluminum-content for HfO₂ and HfAlO films;

FIG. 7 shows flat band voltage (V_{FB}) as a function of aluminum-content for HfO₂ and HfAlO films; and

FIG. 8 shows leakage current density (J_{g}) as a function of EOT for HfO₂ and HfAlO films.

### DETAILED DESCRIPTION OF SEVERAL EMBODIMENTS

Embodiments of the invention are described below in reference to the Figures.

According to one embodiment, a method is provided for forming a semiconductor device. The method includes depositing an aluminum-doped high-k film by ALD that includes a) pulsing a metal-containing precursor into a process chamber containing a substrate, b) pulsing an aluminum-containing precursor into the process chamber, where a) and b) are sequentially performed without an intervening oxidation step, and c) pulsing an oxygen-containing precursor into the process chamber. The method can further include repeating a)-c) until the aluminum-doped high-k film has a desired thickness and heat-treating the aluminum-doped high-k film to crystallize or increase the crystallization of the film.

According to one embodiment, aluminum-doped hafnium oxide (HfAlO) films are deposited by ALD using sequential pulsing and purging of the precursors. The HfAlO films preferably have a low Al content, where the Al content is calculated using Al/(Al+Hf)×100%. Unlike other deposition methods, the current method provides a process for forming very thin HfAlO films with low Al content and with very precise control over the low Al content. According to some embodiments, the Al content can be less than about 10 atomic percent Al, less than about 6 atomic percent Al, less than about 5 atomic percent Al, less than about 3 atomic percent Al, or less than about 2 atomic percent Al.

The HfAlO films may be heat-treated in in a post deposition anneal to achieve an increase in the dielectric constant (k) through a crystallization change to the higher-k tetragonal or cubic phases, where the low Al content stabilizes the crystallization form. The crystallization temperature can be carefully engineered to work with gate-first and gate-last integration schemes. Further, compared to HfO₂ films, the HfAlO films showed improvement in effective oxide thickness (EOT), gate leakage current density, and no detrimental impact on flat band voltage. Embodiments of the invention allow for simple integration of the HfAlO films in both negative-channel metal-oxide semiconductor (NMOS) and positive-channel metal-oxide semiconductor (PMOS) devices, and gate first and gate last integration schemes used in semiconductor manufacturing. No reduction was observed in the interface (SiO₂) thickness when compared to annealed HfO₂ films, indicating the absence of interface scavenging effects by the HfAlO films.

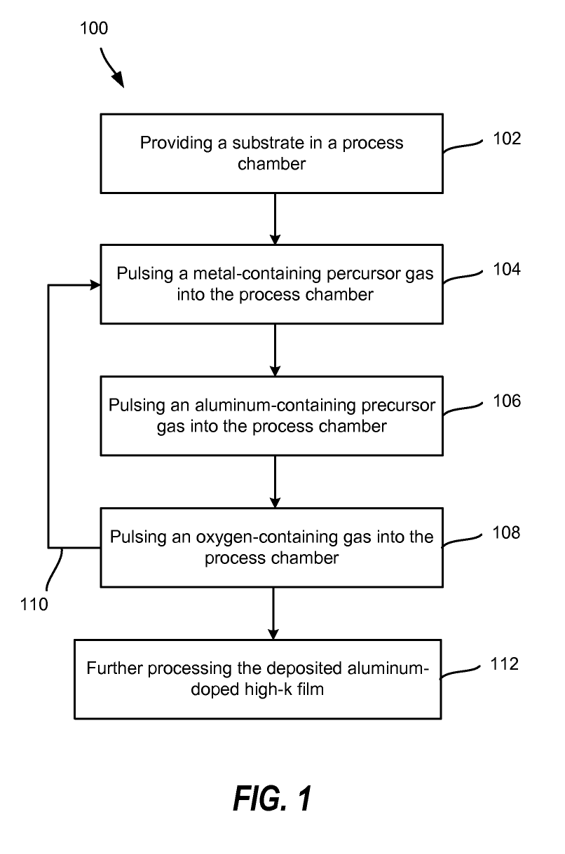

FIG. 1 shows a process flow diagram for forming a semiconductor device according to an embodiment of the invention. The process flow 100 provides a method for depositing an aluminum-doped high-k film on a substrate by ALD. The process flow 100 includes, in 102, providing a substrate in a process chamber. The substrate can, for example, include silicon, germanium, silicon germanium, or compound semiconductors.

In 104, a metal-containing precursor is pulsed into the process chamber. The metal-containing precursor exposure may be long enough to saturate the substrate surface with adsorbed precursor or, alternatively, the exposure may be shorter and not fully saturate the substrate surface with adsorbed metal-containing precursor. The metal-containing precursor can, for example, contain hafnium, zirconium, titanium, a rare earth element, or a combination thereof. The hafnium-containing precursor can, for example, include Hf(O^{t}Bu)₄ (hafnium tert-butoxide, HTB), Hf(NEt₂)₄ (tetrakis(diethylamido)hafnium, TDEAHf), Hf(NEtMe)₄ (tetrakis(ethylmethylamido)hafnium, TEMAHf), Hf(NMe₂)₄ (tetrakis(dimethylamido)hafnium, TDMAHf), or a combination thereof. The zirconium-containing precursor can, for example, contain Zr(O^{t}Bu)₄ (zirconium tert-butoxide, ZTB), Zr(NEt₂)₄ (tetrakis(diethylamido)zirconium, TDEAZr), Zr(NEtMe)₄ (tetrakis(ethylmethylamido)zirconium, TEMAZr), Zr(NMe₂)₄ (tetrakis(dimethylamido)zirconium, TDMAHf), or a combination thereof. The titanium-containing precursors can include Ti(OiPr)₄, Ti(O^{t}Bu)₄ (titanium tert-butoxide, TTB), Ti(NEt₂)₄ (tetrakis(diethylamido)titanium, TDEAT), Ti(NMeEt)₄ (tetrakis(ethylmethylamido)titanium, TEMAT), Ti(NMe₂)₄ (tetrakis(dimethylamido)titanium, TDMAT), Ti(THD)₃ (tris(2,2,6,6-tetramethyl-3,5-heptanedionato)titanium), or a combination thereof.

In 106, an aluminum-containing precursor is pulsed into the process chamber. The aluminum-containing precursor exposure may be long enough to saturate the substrate surface with adsorbed aluminum-containing precursor or, alternatively, the exposure may be shorter and not fully saturate the substrate surface with adsorbed aluminum-containing precursor. The aluminum-containing precursor can, for example, include AlMe₃, AlEt₃, AlMe₂H, [Al(OsBu)₃]₄, Al(CH₃COCHCOCH₃)₃, AlCl₃, AlBr₃, AlI₃, Al(OiPr)₃, [Al(NMe₂)₃]₂, Al(iBu)₂Cl, Al(iBu)₃, Al(iBu)₂H, AlEt₂Cl, Et₃Al₂(OsBu)₃, Al(THD)₃, H₃AlNMe₃, H₃AlNEt₃, H₃AlNMe₂Et, H₃AlMeEt₂, and combination thereof.

In 108, an oxygen-containing gas is pulsed into the process chamber to react with the adsorbed metal-containing precursor and the aluminum-containing precursor. The oxygen-containing precursor can, for example, include ozone (O₃), water (H₂O), O₂, or a combination thereof. The oxygen-containing gas can further include a noble gas, for example Argon (Ar).

The resulting aluminum-doped high-k film can contain hafnium, zirconium, titanium, a rare earth element, or a combination thereof. Examples include HfAlO, ZrAlO, TiAlO, and ReAlO, where Re refers to a rare earth metal.

It is believed that the exposure in 106 results in a reaction between the adsorbed metal-containing precursor and the aluminum-containing precursor. This allows for very good control over the aluminum content in the resulting high-k film and enables formation of aluminum-doped high-k films with very low aluminum content. Such low aluminum content is difficult to achieve using conventional ALD. The exposures in 104 and 106 are sequentially performed without an intervening oxidation step (i.e., no exposure to O₃, H₂O, or O₂), thus the adsorbed metal-containing precursor from step 104 and the adsorbed aluminum-containing precursor from step 106 are not oxidized until during the oxygen-containing gas exposure in 106. The process flow 100 is different from conventional ALD where an oxygen-containing gas is exposed to that substrate after the exposure in 104 and before the exposure in 106.

In one example, an aluminum-doped HfO₂ film may be deposited according to embodiments of the invention using a hafnium-containing precursor that includes TEMAHf and an aluminum-containing precursor that includes trimethylaluminum (AlMe₃).

According to some embodiments, the process flow 100 can further include purging and/or evacuation steps between one or more of the steps 102, 104, 106, and 108. The purging can include purging the process chamber with a noble gas, for example Argon (Ar). Further, as indicated by process arrow 110, steps 104-108 may be repeated any number of times until the high-k film has a desired thickness.

The substrate temperature may be selected to enable ALD processing and the temperature can be between about 20° C. and about 500° C., between about 20° C. and about 300° C., between about 20° C. and about 200° C., between about 20° C. and about 100° C., between about 100° C. and about 500° C., between about 200° C. and about 500° C., between about 300° C. and about 500° C., between about 20° C. and about 500° C., or between about 200° C. and about 300° C. In one example, the substrate temperature can be about 250° C.

Still referring to FIG. 1, in 112, the deposited aluminum-doped high-k film may be further processed. The further processing can include a high-temperature heat-treating to crystallize or increase the crystallinity of the aluminum-doped high-k film, thereby lowering the EOT. The substrate heat-treating temperature may be the same or higher than that of the ALD processing in steps 104-108.

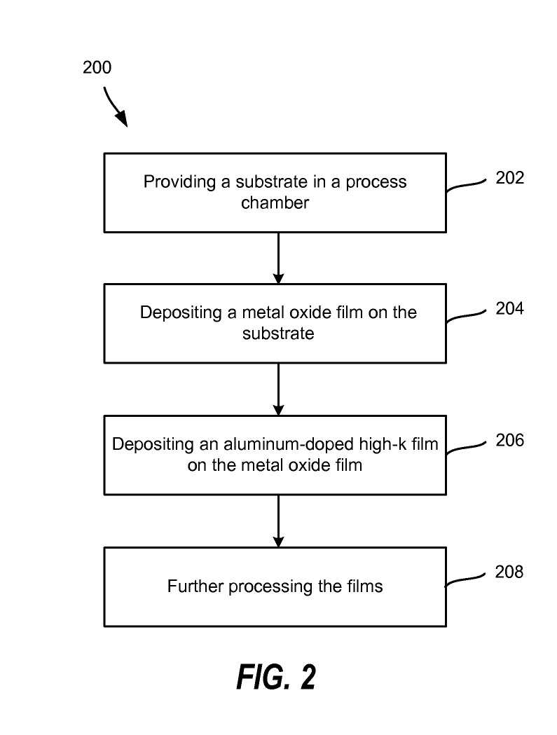

FIG. 2 shows a process flow diagram for forming a semiconductor device according to another embodiment of the invention. The process flow 200 provides a method for depositing an aluminum-doped high-k film on a substrate by ALD in a multilayer deposition process. The process flow 200 includes, in 202, providing a substrate in a process chamber. In 204, a metal oxide film is deposited on the substrate by ALD or chemical vapor deposition (CVD).

The metal oxide film may be deposited by ALD using alternating exposures of a metal-containing precursor and an oxygen-containing gas. In 206, an aluminum-doped high-k film is deposited on the metal oxide film. The aluminum-doped high-k film may be deposited as described above in reference to FIG. 1. The metal oxide film and the aluminum-doped high-k film can contain hafnium, zirconium, titanium, a rare earth element, or a combination thereof. Examples include HfO₂, ZrO₂, TiO₂, ReOx, HfAlO, ZrAlO, TiAlO, and ReAlO, where Re refers to a rare earth metal.

In 208, the multilayer high-k film containing the metal oxide film on the substrate and the aluminum-doped high-k film on the metal oxide film may be further processed. The further processing can include a high-temperature heat-treating to crystallize or increase the crystallinity of the multilayer high-k film. Further, the heat-treating may be utilized to diffuse aluminum from the aluminum-doped high-k film into the metal oxide film, thereby reducing the aluminum content of the aluminum-doped high-k film and introducing aluminum into the underlying metal oxide film. Thus, after the heat-treating, the aluminum is distributed among both the aluminum-doped high-k film and the metal oxide film. The resulting aluminum-doped high-k film can have very low aluminum-content, for example less than about 6% Al.

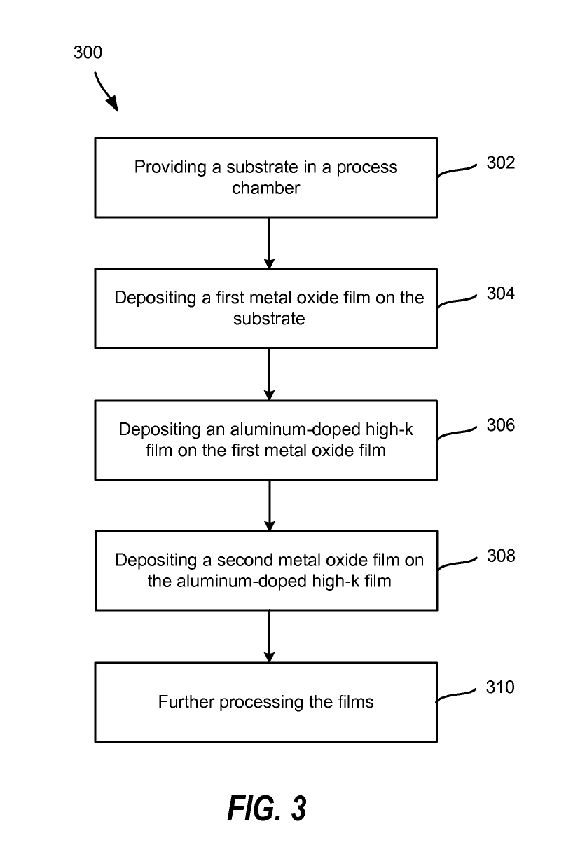

FIG. 3 shows a process flow diagram for forming a semiconductor device according to another embodiment of the invention. The process flow 300 provides a method for depositing an aluminum-doped high-k film on a substrate by ALD in a multilayer deposition process. The process flow 300 is similar to the process flow 200 in FIG. 2 and includes, in 302, providing a substrate in a process chamber. In 304, a first metal oxide film is deposited on the substrate by ALD or CVD. In 306, an aluminum-doped high-k film is deposited on the first metal oxide film. The aluminum-doped high-k film may be deposited as described above in reference to FIG. 1.

In 308, a second metal oxide film is deposited on the aluminum-doped high-k film. The first and second metal oxide films and the aluminum-doped high-k film can contain hafnium, zirconium, titanium, a rare earth element, or a combination thereof. Examples include HfO₂, ZrO₂, TiO₂, ReO, HfAlO, ZrAlO, TiAlO, and ReAlO, where Re refers to a rare earth metal.

In 310, the deposited multilayer high-k film may be further processed. The further processing can include a high-temperature heat-treating to crystallize or increase the crystallinity of the multilayer high-k film. Further, the heat-treating may diffuse aluminum from the aluminum-doped high-k film into the first and second metal oxide films, thereby reducing the aluminum content of the aluminum-doped high-k film and introducing aluminum into the underlying and overlying first and second metal oxide films. Thus, after the heat-treating, the aluminum is distributed among the aluminum-doped high-k film and the first and second metal oxide films. The resulting aluminum-doped high-k film can have very low aluminum-content, for example less than about 6% Al.

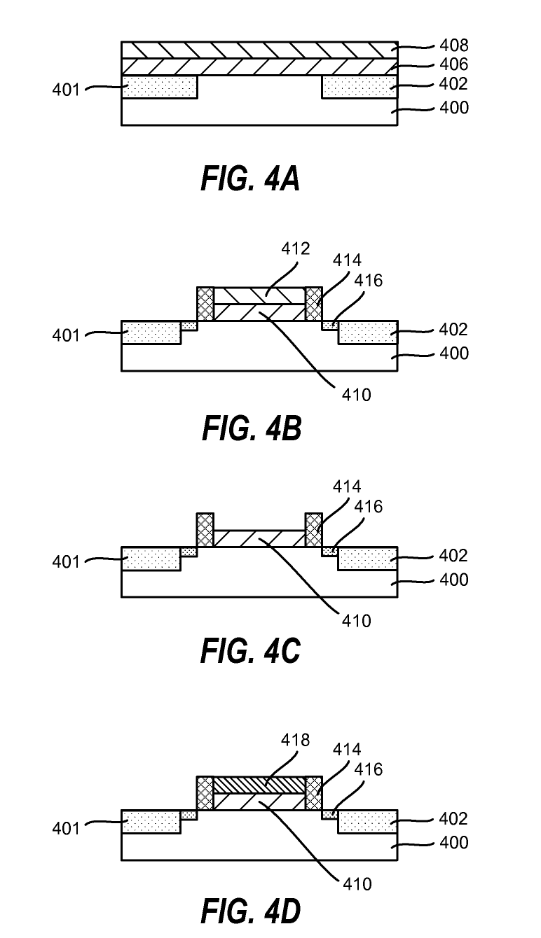

FIGS. 4A-4D show through cross-sectional views a method for forming a semiconductor device according to an embodiment of the invention.

FIG. 4A shows a film structure containing a substrate 400, a source region 401, a drain region 402, an aluminum-doped high-k film 406, and a dummy gate layer 408 (e.g., poly-Si). The aluminum-doped high-k film 406 may be formed as described in FIGS. 1-3. FIG. 4B shows a film structure after further processing and includes a patterned aluminum-doped high-k film 410, patterned dummy gate layer 412, sidewall spacers 414, and shallow doping region 416. Thereafter, the patterned dummy gate layer 412 may be removed as shown in FIG. 4C and thereafter a patterned metal gate layer 418 formed on the aluminum-doped high-k film 406 as shown in FIG. 4D. Examples of the patterned metal gate layer 418 include TiN, TiSiN, and TiC. The method shown in FIGS. 4A-4D is an example of a gate-first integration process and the aluminum-doped high-k film 406 may be heat-treated at any point in the process flow.

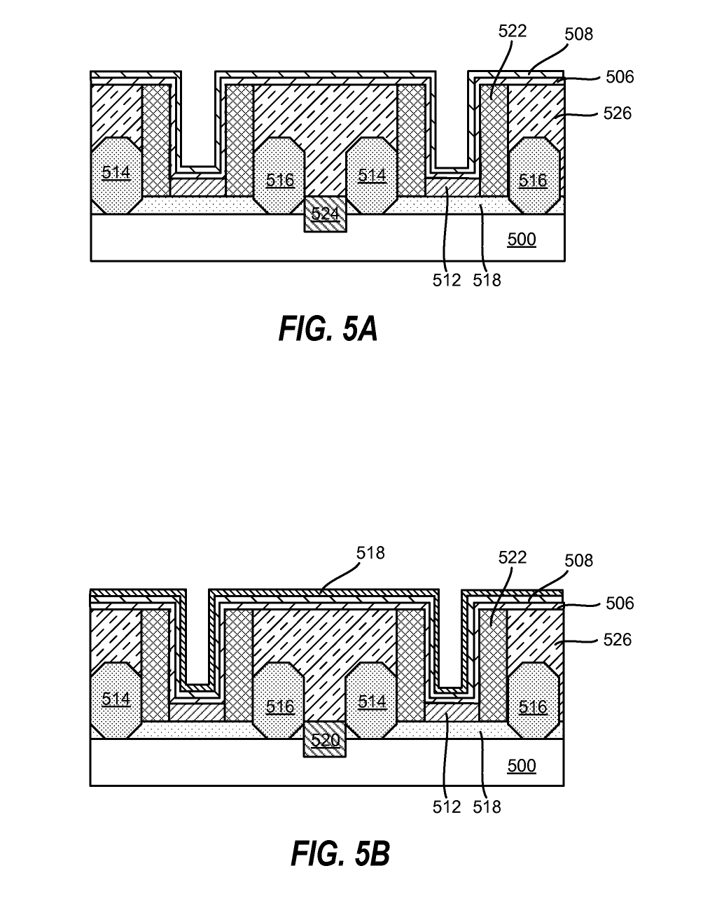

FIGS. 5A-5B show through cross-sectional views a method for forming a semiconductor device according to another embodiment of the invention. FIG. 5A shows a film structure containing a substrate 500, source regions 514, drain regions 516, channel region 518, shallow trench isolation (STI) 524, interface layer 512, sidewall spacers 522, interlayer dielectric (ILD) 526, metal oxide film 506 (e.g., HfO₂), and aluminum-doped high-k film 508 (e.g., HfAlO). The metal oxide film 506 and the aluminum-doped high-k film 508 may be formed as described above for FIGS. 1-3. The method is an example of a gate-last integration process and the aluminum-doped high-k film 508 may be heat-treated at any point in the process flow.

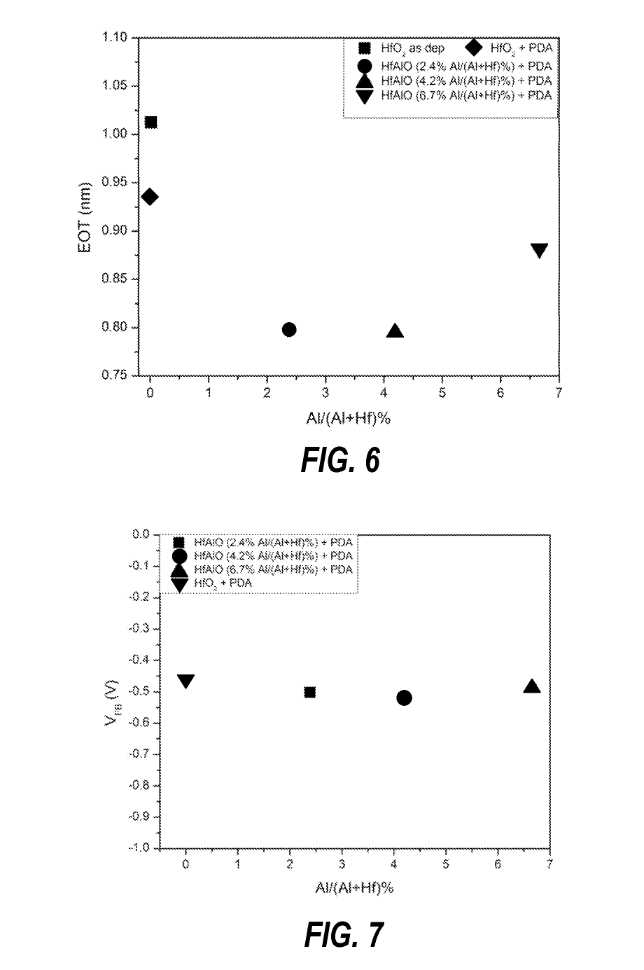

FIG. 6 shows equivalent oxide thickness (EOT) as a function of aluminum content for HfO₂ and HfAlO films. The films that were analyzed included as deposited HfO₂, HfO₂ heat-treated by post-deposition anneal (PDA), and HfAlO heat-treated by PDS. The aluminum-content of the different HfAlO films was 2.4%, 4.2%, and 6.7% Al. The results in FIG. 6 shows that the HfAlO films had lower EOT than the HfO₂ films, particularly HfAlO films with aluminum content less than 5% Al, and that the EOT increased for HfAlO films with high aluminum content (greater than about 6%). In one example, the HfAlO films had lower EOT than the HfO₂ films by a factor of about 1.5.

FIG. 7 shows flat band voltage (V_{FB}) as a function of aluminum-content for HfO₂ and HfAlO films. The films that were analyzed included as deposited HfO₂, heat-treated (PDA) HfO₂, and heat-treated HfAlO (aluminum-content of 2.4%, 4.2%, and 6.7% Al). The results in FIG. 7 show that the HfO₂ and HfAlO films had about the same V_{FB}. This shows that adding aluminum to the HfO₂ films did not change V_{FB}. This allows for using the HfO₂ and HfAlO films for both NMOS and PMOS devices, which results in simple integration of these films into semiconductor devices.

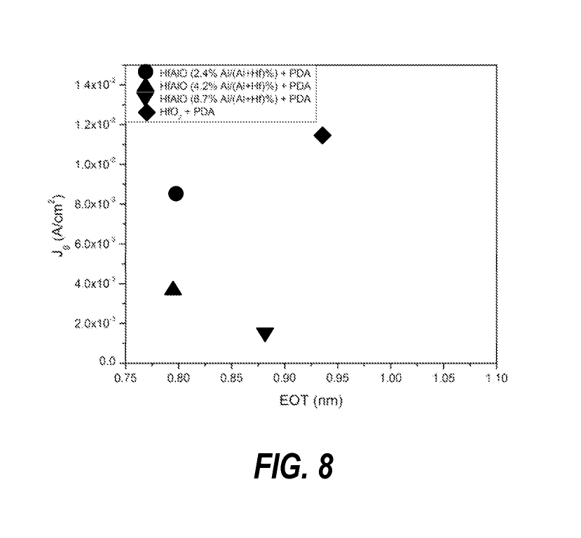

FIG. 8 shows leakage current density (Jg) as a function of EOT for HfO₂ and HfAlO films. The films that were analyzed included heat-treated (PDA) HfO₂ and heat-treated HfAlO (aluminum-content of 2.4%, 4.2%, and 6.7% Al). The results in FIG. 8 show that leakage current density for the HfAlO films was reduced by about a factor of 10 compared to HfO₂.

A plurality of embodiments for forming a semiconductor device have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. It is therefore intended that the scope of the invention be limited not by this detailed description, but rather by the claims appended hereto.

What is claimed is:

1. A method for forming a semiconductor device, the method comprising:
depositing an aluminum-doped high-k film on a substrate by atomic layer deposition (ALD) that includes:
a) pulsing a metal-containing precursor gas into a process chamber containing the substrate,
b) pulsing an aluminum-containing precursor gas into the process chamber, wherein a) and b) are sequentially performed without an intervening oxidation step, and
c) pulsing an oxygen-containing gas into the process chamber.

2. The method of claim 1, wherein the metal-containing precursor gas includes hafnium, zirconium, titanium, a rare earth element, or a combination thereof.

3. The method of claim 1, further comprising
repeating a)-c) until the aluminum-doped high-k film has a desired thickness.

4. The method of claim 1, further comprising
d) heat-treating the aluminum-doped high-k film to crystallize or increase the crystallization of the film.

5. The method of claim 1, wherein the aluminum-content of the aluminum-doped high-k film is less than 6 atomic percent Al.

6. A method for forming a semiconductor device, the method comprising:
depositing a first metal oxide film on a substrate; and
depositing an aluminum-doped high-k film on the first metal oxide film, wherein the aluminum-doped high-k film is deposited by atomic layer deposition (ALD) that includes:
a) pulsing a metal-containing precursor gas into a process chamber containing the substrate,
b) pulsing an aluminum-containing precursor gas into the process chamber, wherein a) and b) are sequentially performed without an intervening oxidation step, and
c) pulsing an oxygen-containing gas into the process chamber.

7. The method of claim 6, wherein the metal-containing precursor includes hafnium, zirconium, titanium, a rare earth element, or a combination thereof.

8. The method of claim 6, further comprising
repeating a)-c) until the aluminum-doped high-k film has a desired thickness.

9. The method of claim 6, further comprising
d) heat-treating the aluminum-doped high-k film to crystallize or increase the crystallization of the aluminum-doped high-k film.

10. The method of claim 9, wherein the heat-treating diffuses aluminum from the aluminum-doped high-k film into the first metal oxide film.

11. The method of claim 9, wherein the aluminum-content of the heat-treated aluminum-doped high-k film is less than 6 atomic percent Al.

12. The method of claim 6, further comprising
depositing a second metal oxide film on the aluminum-doped high-k film.

13. The method of claim 12, further comprising
d) heat-treating the aluminum-doped high-k film to crystallize or increase the crystallization of the aluminum-doped high-k film.

14. The method of claim 13, wherein the heat-treating diffuses aluminum from the aluminum-doped high-k film into the first and second metal oxide films.

15. The method of claim 13, wherein the aluminum-content of the heat-treated aluminum-doped high-k film is less than 6 atomic percent Al.

16. A method for forming a semiconductor device, the method comprising:
depositing a first HfO₂ film on a substrate;
depositing an aluminum-doped HfO₂ film on the first HfO₂ film, wherein the aluminum-doped HfO₂ film is deposited by atomic layer deposition (ALD) that includes:
a) pulsing a hafnium-containing precursor gas into a process chamber containing a substrate,
b) pulsing an aluminum-containing precursor gas into the process chamber, wherein a) and b) are sequentially performed without an intervening oxidation step, and
c) pulsing an oxygen-containing gas into the process chamber; and
depositing a second HfO₂ film on the aluminum-doped HfO₂ film.

17. The method of claim 16, further comprising
repeating a)-c) until the aluminum-doped high-k film has a desired thickness.

18. The method of claim 16, further comprising
e) heat-treating the aluminum-doped HfO₂ film to crystallize or increase the crystallization of the aluminum-doped HfO₂ film.

19. The method of claim 18, wherein the heat-treating diffuses aluminum from the aluminum-doped HfO₂ film into the first and second HfO₂ films.

20. The method of claim 18, wherein the aluminum-content of the heat-treated aluminum-doped HfO₂ film is less than 6 atomic percent Al.

21. The method of claim 1, wherein the metal-containing precursor is tetrakis(ethylmethylamido)hafnium.

22. The method of claim 1, wherein the aluminum-containing precursor is trimethylaluminum.
